(19) United States
(12) Patent Application Publication
(10) Pub. No.: US 2023/0163261 A1
(43) Pub. Date: May 25, 2023

(54) Processing Method of LED Display Module

(71) Applicant: LEYARD OPTOELECTRONIC CO., LTD., Beijing (CN)

(72) Inventors: Changjun LU, Beijing (CN); Li MA, Beijing (CN)

(21) Appl. No.: 17/992,955

(22) Filed: Nov. 23, 2022

(30) Foreign Application Priority Data
Nov. 24, 2021 (CN) 202111408847.X

(51) Int. Cl. H01L 33/56; H01L 25/075; H01L 33/00; H01L 33/38

(52) U.S. Cl. CPC H01L 33/56; H01L 25/0753; H01L 33/005; H01L 33/38; H01L 2933/005; H01L 2933/0016

(57) ABSTRACT

Provided is a processing method of an LED display module. The processing method of the LED display module includes following steps: acquiring a first LED chip emitting blue light and a second LED chip emitting blue light, a wavelength of the first LED chip being smaller than a wavelength of the second LED chip; placing the first LED chip on a first temporary substrate with a front surface of the first LED chip facing upward, and placing the second LED chip on a second temporary substrate with a front surface of second LED chip facing upward; fixing a plurality of display units to a substrate, each of the plurality of display units including two first packages and one second package; spraying a red quantum layer on a front surface of one of the two first packages to obtain a red quantum package; spraying a green quantum layer on a front surface of the other one of the two first packages to obtain a green quantum package; and a front surface of the red quantum package, a front surface of the green quantum package and a front face of the second package being flush. A technical solution of the application effectively solves a problem that a quantum dot LED display module is difficult to prepare in the related art.

### CROSS-REFERENCE TO RELATED APPLICATION

The present disclosure claims the priority to Chinese Patent Application No. 202111408847.X, filed to the Chinese Patent Office on Nov. 24, 2021 and entitled “Processing Method of LED Display Module”, which is incorporated in its entirety herein by reference.

### TECHNICAL FIELD

The disclosure relates to a field of Light Emitting Diode (LED) display, in particular to a processing method of an LED display module.

### BACKGROUND

A quantum dot is a three-dimensional semiconductor nanostructure, which can be electro-induced or photo-induced to emit light. A color of emitted light is related to a size of the quantum dot. The quantum dot is non-water-resistant, non-oxygen-resistant and non-temperature-resistant, and is mainly prepared into a quantum dot film in a related art, which is used as a color conversion film. In LED direct display, an LED is arranged in front of a screen as a direct display unit.

China patent application with a publication number of CN109979960A discloses a quantum dot LED display technology. Grooves are etched on a substrate, and quantum dots are filled into the grooves to form a quantum dot substrate. Then the quantum dot substrate and a display substrate are butted to prepare the quantum dot LED display module.

By adopting the above method, a requirement of a precision of butt joint between the quantum dot substrate and the display substrate is high. When a position of an LED chip is offset, the quantum dot substrate and the display substrate are difficult to butt, and it is difficult to prepare the quantum dot LED display module.

### SUMMARY

The disclosure aims to provide a processing method of an LED display module, so as to solve a problem that a quantum dot LED display module is difficult to prepare in a related art.

In order to achieve the above purpose, the disclosure provides a processing method of an LED display module. The processing method of the LED display module includes following steps: acquiring a first LED chip emitting blue light and a second LED chip emitting blue light, a wavelength of the first LED chip being smaller than a wavelength of the second LED chip; placing the first LED chip on a first temporary substrate with a front surface of the first LED chip facing upward, and placing the second LED chip on a second temporary substrate with a front surface of second LED chip facing upward; packaging a bottom and a side of the first LED chip with a first reflective adhesive, and packaging a bottom and a side of the second LED chip with a second reflective adhesive; packaging the front surface of the first LED chip with a first isolation layer, and packaging the front surface of the second LED chip with a second isolation layer; removing the first temporary substrate to obtain a first package containing the first LED chip, and removing the second temporary substrate to obtain a second package containing the second LED chip, a height of the second package being greater than a height of the first package; fixing a plurality of display units to a substrate, each of the plurality of display units including two first packages and one second package; spraying a red quantum layer on a front surface of one of the two first packages to obtain a red quantum package; spraying a green quantum layer on a front surface of the other one of the two first packages to obtain a green quantum package; and a front surface of the red quantum package, a front surface of the green quantum package and a front face of the second package being flush.

In some embodiments, after a step of fixing the plurality of display units to the substrate, each of the plurality of display units including two first packages and one second package; spraying the red quantum layer on the front surface of one of the two first packages to obtain the red quantum package; spraying the green quantum layer on the front surface of the other one of the two first packages to obtain the green quantum package; and the front surface of the red quantum package, the front surface of the green quantum package and the front face of the second package being flush, the processing method of the LED display module further includes: filling an area outside the red quantum package, the green quantum package and the second package on the substrate with a light-absorbing adhesive layer, a front surface of the light-absorbing adhesive layer being flush with the front surface of the red quantum package, the front surface of the green quantum package and the front surface of the second package.

In some embodiments, after a step of filling the area outside the red quantum package, the green quantum package and the second package on the substrate with the light-absorbing adhesive layer, the front surface of the light-absorbing adhesive layer being flush with the front surface of the red quantum package, the front surface of the green quantum package and the front surface of the second package, the processing method of the LED display module further includes: packaging a display module containing the light-absorbing adhesive layer with a protective layer, a light transmittance of the protective layer being greater than or equal to 30%.

In some embodiments, before a step of placing the first LED chip on the first temporary substrate with the front surface of the first LED chip facing upward, and placing the second LED chip on the second temporary substrate with the front surface of second LED chip facing upward, the processing method of the LED display module further includes: coating the first temporary substrate with a first release agent or a first release adhesive, and coating the second temporary substrate with a second release agent or a second release adhesive.

In some embodiments, in a step of packaging the bottom and the side of the first LED chip with the first reflective adhesive, and packaging the bottom and the side of the second LED chip with the second reflective adhesive, a thickness of the first reflective adhesive located outside the side of the first LED chip is greater than a first thickness, the first thickness being a sum of a thickness of an epitaxial layer of the first LED chip and a thickness of an electrode of the first LED chip; and a thickness of the second reflective adhesive located outside the side of the second LED chip is greater than a second thickness, the second thickness being a sum of a thickness of an epitaxial layer of the second LED chip and a thickness of an electrode of the second LED chip.

In some embodiments, the thickness of the first reflective adhesive located outside the side of the first LED chip is smaller than a thickness of the first LED chip, a thickness of the first LED chip is equal to a sum of a thickness of a substrate of the first LED chip, the thickness of the epitaxial layer of the first LED chip and the thickness of the electrode of the first LED chip. The thickness of the second reflective adhesive located outside the side of the second LED chip is smaller than a thickness of the second LED chip, the thickness of the second LED chip being equal to a sum of a thickness of the substrate of the second LED chip, the thickness of the epitaxial layer of the second LED chip and the thickness of the electrode of the second LED chip.

In some embodiments, in the step of placing the first LED chip on the first temporary substrate with the front surface of the first LED chip facing upward, and placing the second LED chip on the second temporary substrate with the front surface of second LED chip facing upward, a plurality of first LED chips and a plurality of second LED chips are arranged at intervals. In a step of removing the first temporary substrate to obtain the first package containing the first LED chip, and removing the second temporary substrate to obtain the second package containing the second LED chip, after the first temporary substrate is removed, a plurality of first packages containing the first LED chip are obtained by performing cutting with one first LED chip as a unit, and after the second temporary substrate is removed, a plurality of second packages containing the second LED chip are obtained by performing cutting with one second LED chip as a unit.

In some embodiments, in the step of removing the first temporary substrate to obtain the first package containing the first LED chip, and removing the second temporary substrate to obtain the second package containing the second LED chip, a ratio of a volume of the first package to a volume of the first LED chip ranges from 1.1 to2, and a ratio of a volume of the second package to a volume of the second LED chip ranges from 1.1 to 2.

In some embodiments, the wavelength of the first LED chip ranges from 440 nm to 460 nm, and the wavelength of the second LED chip ranges from 460 nm to 475 nm.

In some embodiments, in the step of packaging the bottom and the side of the first LED chip with the first reflective adhesive, and packaging the bottom and the side of the second LED chip with the second reflective adhesive, a reflectivity of the first reflective adhesive is between 85% and 100%, and a reflectivity of the second reflective adhesive is between 85% and 100%.

In some embodiments, in a step of packaging the front surface of the first LED chip with the first isolation layer, and packaging the front surface of the second LED chip with the second isolation layer, the first isolation layer includes a first epoxy resin or a first silica gel, and the second isolation layer includes a second epoxy resin or a second silica gel.

By applying a technical solution of the disclosure, the processing method of the LED display module includes following steps: acquiring the first LED chip emitting blue light and the second LED chip emitting blue light, the wavelength of the first LED chip being smaller than the wavelength of the second LED chip; placing the first LED chip on the first temporary substrate with the front surface of the first LED chip facing upward, thus, the first temporary substrate bears the first LED chip, facilitating packaging the first LED chip; and placing the second LED chip on the second temporary substrate with the front surface of second LED chip facing upward, thus, the second temporary substrate bears the second LED chip, facilitating packaging the second LED chip; packaging the bottom and the side of the first LED chip with the first reflective adhesive, and packaging the bottom and the side of the second LED chip with the second reflective adhesive, the first reflective adhesive reflects a light of the first LED chip, improving a light utilization rate of the first LED chip, and the second reflective adhesive reflects a light of the second LED chip, improving a light utilization rate of the second LED chip; packaging the front surface of the first LED chip with the first isolation layer, and packaging the front surface of the second LED chip with the second isolation layer; removing the first temporary substrate to obtain the first package containing the first LED chip, and removing the second temporary substrate to obtain the second package containing the second LED chip, a height of the second package being greater than a height of the first package; fixing the plurality of display units to the substrate, each of the plurality of display units including two first packages and one second package; spraying the red quantum layer on the front surface of one of the two first packages to obtain the red quantum package; spraying the green quantum layer on the front surface of the other one of the two first packages to obtain the green quantum package; and the front surface of the red quantum package, the front surface of the green quantum package and the front face of the second package being flush. The first isolation layer protects the front surface of the first LED chip and blocks a heat of the first LED chip from being directly conducted to the red quantum layer, which reduces an influence of the heat on the red quantum layer. The second isolation layer protects the front surface of the second LED chip and blocks a heat of the second LED chip from being directly conducted to the green quantum layer, which reduces an influence of the heat on the green quantum layer. Thus, the LED display module obtained by the processing method of the LED display module does not need to adopt the method of butting a quantum dot substrate and a display substrate in the related art, and does not need to consider an offset of position of the LED chip, so that the LED display module is easily processed. Therefore, the technical solution of the application solves the problem that a quantum dot LED display module is difficult to prepare in the related art.

### BRIEF DESCRIPTION OF THE DRAWINGS

The drawings consisting of a part of the disclosure are used for further understanding of the present disclosure. The schematic embodiments and description thereof are used for explaining the disclosure and do not limit the disclosure improperly. In the drawings,

FIG. 1 illustrates a flowchart of an embodiment of a processing method of an LED display module according to the disclosure.

FIG. 2 illustrates a structural schematic diagram of a first LED chip being placed on a first temporary substrate in the processing method of the LED display module of FIG. 1.

FIG. 3 illustrates a structural schematic diagram of a first reflective adhesive being packaged on the first LED chip in the processing method of the LED display module of FIG. 1.

FIG. 4 illustrates a structural schematic diagram of a second LED chip being placed on a second temporary substrate in the processing method of the LED display module of FIG. 1.

FIG. 5 illustrates a structural schematic diagram of a second reflective adhesive being packaged on the second LED chip in the processing method of the LED display module of FIG. 1.

FIG. 6 illustrates a structural schematic diagram of a first isolation layer being arranged on the first LED chip in the processing method of the LED display module of FIG. 1.

FIG. 7 illustrates a structural schematic diagram of a second isolation layer being arranged on the second LED chip in the processing method of the LED display module of FIG. 1.

FIG. 8 illustrates a structural schematic diagram of a first package in the processing method of the LED display module of FIG. 1.

FIG. 9 illustrates a structural schematic diagram of a second package in the processing method of the LED display module of FIG. 1.

FIG. 10 illustrates a structural schematic diagram of two first packages and one second package being arranged on a substrate in the processing method of the LED display module of FIG. 1.

FIG. 11 is a structural schematic diagram of a red quantum package, a green quantum package and the second package being arranged on the substrate in the processing method of the LED display module of FIG. 1.

FIG. 12 illustrates a structural schematic diagram after the substrate is filled with a light-absorbing adhesive layer in the processing method of the LED display module of FIG. 1.

FIG. 13 illustrates a structural schematic diagram of a protective layer being arranged on the light-absorbing adhesive layer in the processing method of the LED display module of FIG. 1.

FIG. 14 illustrates a structural schematic diagram of the first LED chip in the processing method of the LED display module of FIG. 1.

FIG. 15 illustrates a structural schematic diagram of the second LED chip in the processing method of the LED display module of FIG. 1.

Herein, the above drawings include the following reference numbers:

1. First package; 2. Second package; 11. First LED chip; 12. Second LED chip; 21. First temporary substrate; 22. Second temporary substrate; 23. Substrate; 31. First reflective adhesive; 32. Second reflective adhesive; 41. First isolation layer; 42. Second isolation layer; 51. Red quantum layer; 52. Green quantum layer; 61. Light-absorbing adhesive layer; and 62. Protective layer.

### DETAILED DESCRIPTION OF THE EMBODIMENTS

The technical solutions in the embodiments of the disclosure will be clearly and completely described below in combination with the drawings in the embodiments of the disclosure. It is apparent that the described embodiments are not all embodiments but part of embodiments of the disclosure. In fact, the description of at least one exemplary embodiment below is merely illustrative, and will not be taken as any limitation to the disclosure and its application or use. All other embodiments obtained by those of ordinary skill in the art on the basis of the embodiments in the disclosure without creative work shall fall within the scope of protection of the disclosure.

It should be noted that the terms used here are only for describing specific implementation modes, and are not intended to limit the exemplary implementation modes according to the application. As used herein, the singular form is also intended to include the plural form unless the context clearly indicates otherwise. In addition, it should also be understood that when the terms “comprising” and/or “including” are used in this specification, same indicate the presence of features, steps, operations, devices, components and/or combinations thereof.

Unless otherwise specified, relative arrangements of parts and steps, digital expressions and values elaborated in these embodiments will not limit the scope of the disclosure. Meanwhile, it should be understood, to facilitate the description, that the sizes of all parts shown in the drawings are not drawn according to an actual proportionate relationship. The technologies, the methods and the equipment known by those of ordinary skill in the art may not be elaborated. However, where appropriate, the technologies, the methods and the equipment should be deemed to be part of the authorized specification. In all examples shown and discussed here, any specific values should be merely explained to be exemplary rather than taken as a limitation. Therefore, other examples of the exemplary embodiments may have different values. It should be noted that the similar reference numbers and letters indicate the similar items in the drawings below, so there is no need to further discuss it in subsequent drawings once an item is defined in one drawing.

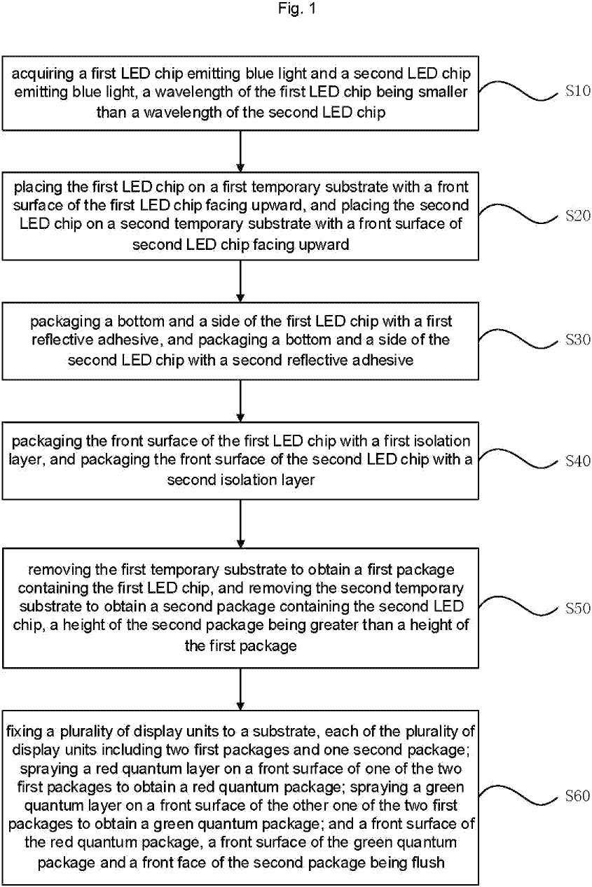

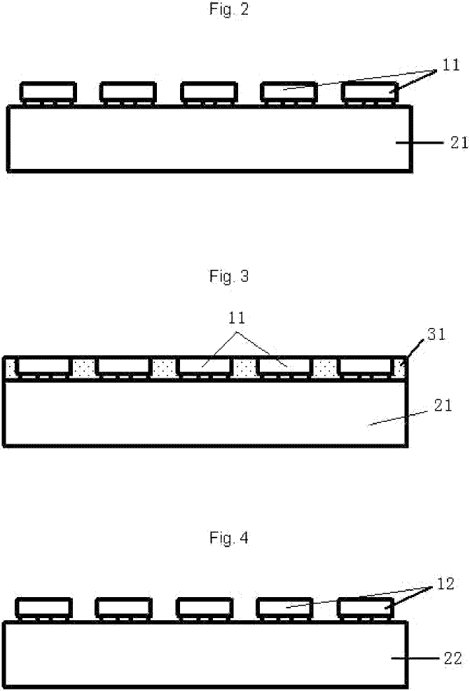

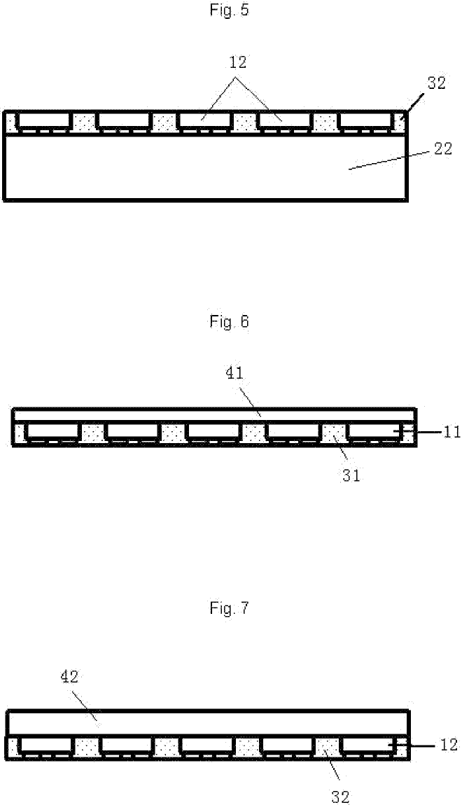

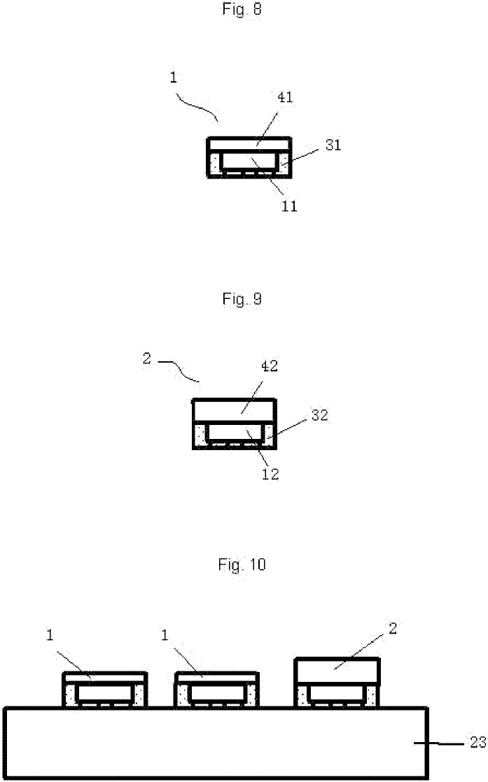

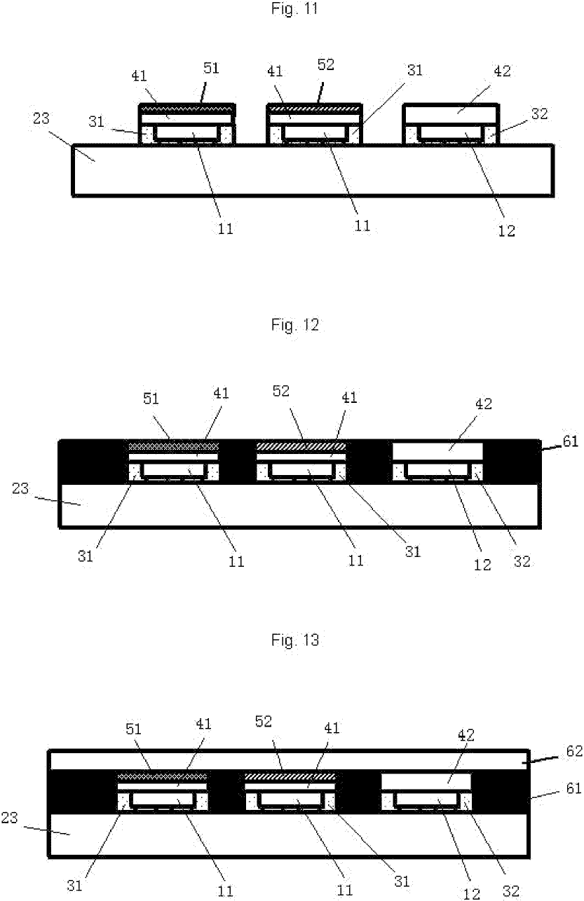

As shown in FIGS. 1 to 13, in a processing method of an LED display module of the embodiments, a processing operation is finished in a vacuum chamber. The processing method of the LED display module includes following steps: at S10, acquiring a first LED chip 11 emitting blue light and a second LED chip 12 emitting blue light, a wavelength of the first LED chip 11 being smaller than a wavelength of the second LED chip 12; at S20, placing the first LED chip 11 on a first temporary substrate 21 with a front surface of the first LED chip 11 facing upward, and placing the second LED chip 12 on a second temporary substrate 22 with a front surface of second LED chip 12 facing upward; at S30, packaging a bottom and a side of the first LED chip 11 with a first reflective adhesive 31, and packaging a bottom and a side of the second LED chip 12 with a second reflective adhesive 32; at S40, packaging the front surface of the first LED chip 11 with a first isolation layer 41, and packaging the front surface of the second LED chip 12 with a second isolation layer 42; at S50, removing the first temporary substrate 21 to obtain a first package 1 containing the first LED chip 11, and removing the second temporary substrate 22 obtain a second package 2 containing the second LED chip 12, a height of the second package 2 being greater than a height of the first package 1; and at S60, fixing a plurality of display units to a substrate 23, each of the plurality of display unit including two first packages 1 and one second package 2; spraying a red quantum layer 51 on a front surface of one of the two first packages 1 to obtain a red quantum package; spraying a green quantum layer 52 on a front surface of the other one of the two first packages 1 to obtain a green quantum package; and a front surface of the red quantum package, a front surface of the green quantum package and a front surface of the second package 2 are flush.

By applying the technical solution of the disclosure, placing the first LED chip 11 on the first temporary substrate 21 with the front surface of the first LED chip 11 facing upward, , thus, the first temporary substrate 21 bears the first LED chip 11, facilitating packaging the first LED chip 11; and placing the second LED chip 12 on the second temporary substrate 22 with the front surface of second LED chip 12 facing upward, thus, the second temporary substrate 22 bears the second LED chip 12, facilitating packaging the second LED chip 12; packaging the bottom and the side of the first LED chip 11 with the first reflective adhesive 31, and packaging the bottom and the side of the second LED chip 12 with the second reflective adhesive 32, the first reflective adhesive 31 reflects a light of the first LED chip 11, improving a light utilization rate of the first LED chip 11, and the second reflective adhesive 32 reflects a light of the second LED chip 12, improving a light utilization rate of the second LED chip 12; packaging the front surface of the first LED chip 11 with the first isolation layer 41, and packaging the front surface of the second LED chip 12 with the second isolation layer 42; removing the first temporary substrate 21 to obtain the first package 1 containing the first LED chip 11, and removing the second temporary substrate 22 obtain the second package 2 containing the second LED chip 12, the height of the second package 2 being greater than the height of the first package 1; fixing the plurality of display units to the substrate 23, each of the plurality of display unit including two first packages 1 and one second package 2; spraying the red quantum layer 51 on the front surface of one of the two first packages 1 to obtain the red quantum package; spraying the green quantum layer 52 on the front surface of the other one of the two first packages 1 to obtain the green quantum package; and the front surface of the red quantum package, the front surface of the green quantum package and the front surface of the second package 2 are flush. Thus, a front surface of each display unit is flat, and a display effect of the display unit is improved. The first isolation layer 41 protects the front surface of the first LED chip 11 and blocks a heat of the first LED chip 11 from being directly conducted to the red quantum layer 51, which reduces an influence of the heat on the red quantum layer 51. The second isolation layer 42 protects the front surface of the second LED chip 12 and blocks a heat of the second LED chip 12 from being directly conducted to the green quantum layer 52, which reduces an influence of the heat on the green quantum layer 52. Thus, the LED display module obtained by the processing method of the LED display module does not need to adopt the method of butting a quantum dot substrate and a display substrate in the related art, and does not need to consider an offset of position of the LED chip, so that the LED display module is easily processed. Therefore, the technical solution of the embodiment solves a problem that the quantum dot LED display module is difficult to prepare in the related art. For convenience of use, both the first temporary substrate 21 and the second temporary substrate 22 withstand a high temperature above 150° C.

It is to be noted that there are at least two first LED chips 11 emitting blue light and at least one second LED chip 12 emitting blue light in the embodiment. A blue light of the first LED chip 11 is converted by the red quantum layer 51, so that the red quantum package emits red light; the blue light of the first LED chip 11 is converted by the green quantum layer 52, so that the green quantum package emits green light; and the second package 2 emits blue light, so that a cost is lower in comparison with using LED chips emitting ultraviolet light.

As shown in FIGS. 1-12, after a step of fixing the plurality of display units to the substrate 23, each of the plurality of display unit including two first packages 1 and one second package 2; spraying the red quantum layer 51 on the front surface of one of the two first packages 1 to obtain the red quantum package; spraying the green quantum layer 52 on the front surface of the other one of the two first packages 1 to obtain the green quantum package; and the front surface of the red quantum package, the front surface of the green quantum package and the front surface of the second package 2 are flush, the processing method of the LED display module further includes: filling an area outside the red quantum package, the green quantum package and the second package 2 on the substrate 23 with a light-absorbing adhesive layer 61, a front surface of the light-absorbing adhesive layer 61 being flush with the front surface of the red quantum package, the front surface of the green quantum package and the front surface of the second package 2. The light-absorbing adhesive layer 61 improves a display contrast of the LED display module. The light-absorbing adhesive layer 61 is preferably ultraviolet curable black glue. The front surface of the light-absorbing adhesive layer 61 is flush with the front surface of the red quantum package, the front surface of the green quantum package and the front surface of the second package 2 to ensure that light emitting surfaces of the plurality of display units are on a same horizontal plane. A display area of each display unit is equal to one pixel.

As shown in FIGS. 1-13, after a step of filling the area outside the red quantum package, the green quantum package and the second package 2 on the substrate 23 with the light-absorbing adhesive layer 61, the front surface of the light-absorbing adhesive layer 61 being flush with the front surface of the red quantum package, the front surface of the green quantum package and the front surface of the second package 2, the processing method of the LED display module further includes: packaging a display module containing the light-absorbing adhesive layer 61 with a protective layer 62, a light transmittance of the protective layer 62 being greater than or equal to 30%. The protective layer 62 blocks light from an outside to the red quantum package, the green quantum package and the second package 2 to avoid an reflection on the front surface of the red quantum package, on the front surface of the green quantum package and on the front surface of the second package 2, and blocks a contact of the red quantum layer 51 and the green quantum layer 52 with air, water and oxygen to protect the red quantum package and the green quantum package. The protective layer 62 is made of epoxy resin, silica gel or a film material. A light transmittance of the protective layer 62 is preferably 30% or 40% or 50% or 60% or 70% or 80% or 90% or 100%.

As shown in FIGS. 1-13, for a convenience of stripping the first LED chip 11 from the first temporary substrate 21 and for a convenience of stripping the second LED chip 12 from the second temporary substrate 22, before a step of placing the first LED chip 11 on the first temporary substrate 21 with the front surface of the first LED chip 11 facing upward, and placing the second LED chip 12 on the second temporary substrate 22 with the front surface of second LED chip 12 facing upward, the processing method of the LED display module further includes: coating the first temporary substrate 21 with a first release agent or a first release adhesive, and coating the second temporary substrate 22 with a second release agent or a second release adhesive.

As shown in FIGS. 1-15, in a step of packaging the bottom and the side of the first LED chip 11 with the first reflective adhesive 31, and packaging the bottom and the side of the second LED chip 12 with the second reflective adhesive 32, a thickness of the first reflective adhesive 31 located outside the side of the first LED chip 11 is greater than a first thickness, and the first thickness is a sum of a thickness of an epitaxial layer of the first LED chip 11 and a thickness of an electrode of the first LED chip 11. Thus, an area around the first LED chip 11 except the front surface of the first LED chip 11 is provided with the first reflective adhesive 31, thus avoiding blue light leakage, and a cost of the first reflective adhesive 31 is reduced at the same time. A thickness of the second reflective adhesive 32 located outside the side of the second LED chip 12 is greater than a second thickness, the second thickness being a sum of a thickness of an epitaxial layer of the second LED chip 12 and a thickness of an electrode of the second LED chip 12. Thus, an area around the second LED chip 12 except the front surface of the second LED chip 12 is provided with the second reflective adhesive 32, thus avoiding blue light leakage, and a cost of the second reflective adhesive 32 is reduced at the same time.

As shown in FIGS. 1-15, the thickness of the first reflective adhesive 31 located outside the side of the first LED chip 11 is smaller than a thickness of the first LED chip 11, the thickness of the first LED chip 11 being equal to a sum of the thickness of a substrate of the first LED chip 11, the thickness of the epitaxial layer of the first LED chip 11 and the thickness of the electrode of the first LED chip 11. Thus, the packaged first reflective adhesive 31 mainly covers the bottom and the side of the first LED chip 11, and the front surface of the first LED chip 11 has no or little first reflective adhesive, so that the front surface of the first LED chip 11 is neat. The thickness of the second reflective adhesive 32 located outside the side of the second LED chip 12 is smaller than a thickness of the second LED chip 12, the thickness of the second LED chip 12 being equal to a sum of a thickness of the substrate of the second LED chip 12, the thickness of the epitaxial layer of the second LED chip 12 and the thickness of the electrode of the second LED chip 12. Thus, the packaged second reflective adhesive 32 mainly covers the bottom and the side of the second LED chip 12, and the front surface of the second LED chip 12 has no or little second reflective adhesive, so that the front surface of the second LED chip 12 is neat.

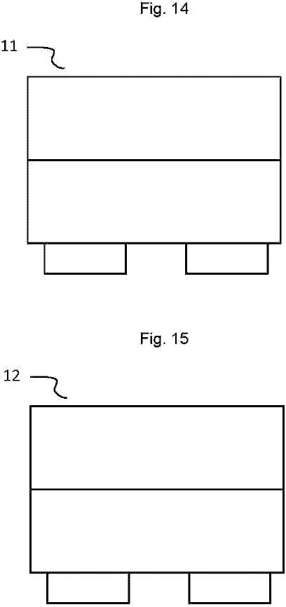

As shown in FIG. 14, the first LED chip 11 includes the substrate (used for supporting the epitaxial layer), the epitaxial layer (used for emitting light), and the electrode arranged in sequence from top to bottom. As shown in FIG. 15, the second LED chip 12 includes the substrate, the epitaxial layer, and the electrode arranged in sequence from top to bottom.

The first reflective adhesive 31 is preferably a first reflective adhesive film, the first reflective adhesive film is used to package the bottom and the side of the first LED chip 11 by mould pressing. Thus, a thickness of the first reflective adhesive film is easy to control, and the first reflective adhesive 31 covers the bottom and the side of the first LED chip 11 more evenly. The second reflective adhesive 32 is preferably a second reflective adhesive film, the second reflective adhesive film is used to package the bottom and the side of the second LED chip 12 by mold pressing. Thus, the second reflective adhesive 32 covers the bottom and the side of the second LED chip 12 more evenly.

As shown in FIGS. 1-15, after the step of packaging a bottom and a side of the first LED chip 11 with a first reflective adhesive 31, and packaging a bottom and a side of the second LED chip 12 with a second reflective adhesive 32, the first reflective adhesive 31 remained on the front surface of the first LED chip 11 is removed by plasma bombardment. Thus, the area around the first LED chip 11 except the front surface of the first LED chip 11 is provided with the first reflective adhesive 31, thus avoiding blue light leakage. The second reflective adhesive 32 remained on the front surface of the second LED chip 12 is removed by plasma bombardment. Thus, the area around the second LED chip 12 except the front surface of the second LED chip 12 is disposed with the second reflective adhesive 32, thus avoiding blue light leakage.

As shown in FIGS. 1-13, in the step of placing the first LED chip 11 on the first temporary substrate 21 with the front surface of the first LED chip 11 facing upward, and placing the second LED chip 12 on the second temporary substrate 22 with the front surface of second LED chip 12 facing upward, a plurality of first LED chips 11 and a plurality of second LED chips 12 are arranged at intervals. In a step of removing the first temporary substrate 21 to obtain the first package 1 containing the first LED chip 11, and removing the second temporary substrate 22 obtain the second package 2 containing the second LED chip 12, in order to separate the plurality of first LED chips 11 into independent units, after the first temporary substrate 21 is removed, a plurality of first packages 1 containing the first LED chip 11 are obtained by performing cutting with one first LED chip 11 as a unit, and in order to separate the plurality of second LED chips 12 into independent units, after the second temporary substrate 22 is removed, a plurality of second packages 2 containing the second LED chip 12 are obtained by performing cutting with one second LED chip 12 as a unit.

As shown in FIGS. 1 to 13, in order to cut a plurality of suitable first packages 1 containing the first LED chip 11 and cut a plurality of suitable second packages 2 containing the second LED chip 12, in the step of removing the first temporary substrate 21 to obtain the first package 1 containing the first LED chip 11, and removing the second temporary substrate 22 obtain the second package 2 containing the second LED chip 12, a ratio of a volume of the first package 1 to a volume of the first LED chip 11 ranges from 1.1 to 2, and a ratio of a volume of the second package 2 to a volume of the second LED chip 12 ranges from 1.1 to 2. Preferably, the ratio of the volume of the first package 1 to the volume of the first LED chip 11 ranges from 1.1 to 1.4, and the ratio of the volume of the second package 2 to the volume of the second LED chip 12 to ranges from 1.1 to 1.4. Specifically, the ratio of the volume of the first package 1 to the volume of the first LED chip 11 is1.1, 1.2, 1.3 or 1.4. Specifically, the ratio of the volume of the second package 2 to the volume of the second LED chip 12 is 1.1, 1.2, 1.3 or 1.4.

As shown in FIGS. 1-13, in order to meet a use requirement, the wavelength of the first LED chip 11 ranges from 440 nm to 460 nm, and the wavelength of the second LED chip 12 ranges from 460 nm to 475 nm. Preferably, the wavelength of the first LED chip 11 is 440 nm or 450 nm or 460 nm, and the wavelength of the second LED chip 12 is 460 nm or 470 nm or 475 nm.

As shown in FIGS. 1-13, in order to meet processing and use requirements, in the step of packaging the bottom and the side of the first LED chip 11 with the first reflective adhesive 31, and packaging the bottom and the side of the second LED chip 12 with the second reflective adhesive 32, a reflectivity of the first reflective adhesive 31 is between 85% and 100%, and a reflectivity of the second reflective adhesive 32 is between 85% and 100%. Preferably, the reflectivity of the first reflective adhesive 31 is 85% or 90% or 100%, and the reflectivity of the second reflective adhesive 32 is 85% or 90% or 100%.

As shown in FIGS. 1-13, in order to better protect the front surface of the first LED chip 11, and at the same time block the heat of the front surface of the first LED chip 11 from being directly conducted to the red quantum layer, so as to avoid affecting a performance of the red quantum layer. Or at the same time block the heat of the front surface of the first LED chip 11 from being directly conducted to the green quantum layer, so as to avoid affecting a performance of the green quantum layer, in a step of packaging the front surface of the first LED chip 11 with the first isolation layer 41, and packaging the front surface of the second LED chip 12 with the second isolation layer 42, the first isolation layer 41 includes a first epoxy resin or a first silica gel, and the second isolation layer 42 includes a second epoxy resin or a second silica gel.

As shown in FIGS. 1-13, in order to transfer and fixe the plurality of display units to the substrate 23 at preset display pixel spacing, in the step of fixing the plurality of display units to the substrate 23, each of the plurality of display unit including two first packages 1 and one second package 2; spraying the red quantum layer 51 on the front surface of one of the two first packages 1 to obtain the red quantum package; spraying the green quantum layer 52 on the front surface of the other one of the two first packages 1 to obtain the green quantum package; and the front surface of the red quantum package, the front surface of the green quantum package and the front surface of the second package 2 are flush, each of the plurality of the display units is fixed to the substrate 23 by welding.

The processing method of the LED display module in the embodiment has low requirements for spraying alignment accuracy of the red quantum layer 51 and the green quantum layer 52. For example, even the red quantum layer 51 and the green quantum layer 52 are sprayed to other places outside the first LED chip 11, the red quantum layer 51(which can be excited by light to emit red light) and the green quantum layer 52 (which can be excited by light to emit green light) sprayed outside the first LED chip 11 can be shielded by the light-absorbing adhesive layer in a subsequent processing. At the same time, a number of thermal processes required by the quantum dot in the process of LED display module processing is reduced, and the thermal process is only required when the protective layer is finally used for packaging. Herein, when the ultraviolet curable black glue is used for packaging, there is no need for thermal process.

The processing method of the LED display module further includes a step of mounting an IC component on a back surface of the substrate 23, and the step of mounting the IC component is performed after a step of processing the front surface of the substrate 23 is completed or before the step of processing the front surface of the substrate 23.

In the description of the disclosure, it is to be understood that orientation or position relationships indicated by terms “front”, “back”, “upper”, “lower”, “left”, “right”, “transverse”, “longitudinal”, “vertical”, “horizontal”, “top”, “bottom” and the like are orientation or position relationships shown in the drawings usually, are adopted not to indicate or imply that indicated devices or components must be in specific orientations or structured and operated in specific orientations but only to conveniently describe the disclosure and simplify descriptions and thus should not be understood as limits to the scope of protection of disclosure. The orientations “inner” and “outer” are the inside and the outside relative to an outline of each part.

For convenient description, spatially relativity terms such as “on”, “above”, “on the surface of”, “on the top of” may be used herein to describe the spatial positional relationship of one device or one feature to other devices or features as shown in the drawings. It will be understood that the spatially relativity terms are intended to encompass different orientations used or operated in addition to the orientations of the devices described in the drawings. For example, if the device in the drawings is inverted, the device described as “on other devices or configurations” or “above other devices or configurations” will then be positioned “under other devices or configurations” or “below other devices or configurations.” Thus, the exemplary term “above” may include both orientations of “above” and “below”. The device may also be positioned in other different ways (rotated 90° or at other orientations) and the spatially relativity description used herein is interpreted accordingly.

In addition, it should be noted that terms “first”, “second” and the like are used for limiting the parts, for facilitating distinguishing corresponding parts only. Unless otherwise stated, the above terms do not have special meanings, and accordingly should not be understood to limit the scope of protection of the disclosure.

The above is only the preferred embodiments of the disclosure and is not used to limit the disclosure. For those skilled in the art, there may be various changes and variations in the disclosure. Any modifications, equivalent replacements, improvements and the like made within the spirit and principle of the disclosure shall fall within the scope of protection of the disclosure.

What is claimed is:

1. A processing method of an LED display module, wherein the processing method of the LED display module comprising following steps:
acquiring a first LED chip emitting blue light and a second LED chip emitting blue light, a wavelength of the first LED chip being smaller than a wavelength of the second LED chip;
placing the first LED chip on a first temporary substrate with a front surface of the first LED chip facing upward, and placing the second LED chip on a second temporary substrate with a front surface of second LED chip facing upward;
packaging a bottom and a side of the first LED chip with a first reflective adhesive, and packaging a bottom and a side of the second LED chip with a second reflective adhesive;
packaging the front surface of the first LED chip with a first isolation layer, and packaging the front surface of the second LED chip with a second isolation layer;
removing the first temporary substrate to obtain a first package containing the first LED chip, and removing the second temporary substrate to obtain a second package containing the second LED chip, a height of the second package being greater than a height of the first package; and
fixing a plurality of display units to a substrate, each of the plurality of display units comprising two first packages and one second package; spraying a red quantum layer on a front surface of one of the two first packages to obtain a red quantum package; spraying a green quantum layer on a front surface of the other one of the two first packages to obtain a green quantum package; and a front surface of the red quantum package, a front surface of the green quantum package and a front surface of the second package being flush.

2. The processing method of the LED display module as claimed in claim 1, wherein after a step of fixing the plurality of display units to the substrate, each of the plurality of display units comprising two first packages and one second package; spraying the red quantum layer on the front surface of one of the two first packages to obtain the red quantum package; spraying the green quantum layer on the front surface of the other one of the two first packages to obtain a green quantum package; and the front surface of the red quantum package, the front surface of the green quantum package and the front surface of the second package being flush, the processing method of the LED display module further comprising: filling an area outside the red quantum package, the green quantum package and the second package on the substrate with a light-absorbing adhesive layer, a front surface of the light-absorbing adhesive layer being flush with the front surface of the red quantum package, the front surface of the green quantum package and the front surface of the second package.

3. The processing method of the LED display module as claimed in claim 2, wherein after a step of filling the area outside the red quantum package, the green quantum package and the second package on the substrate with the light-absorbing adhesive layer, the front surface of the light-absorbing adhesive layer being flush with the front surface of the red quantum package, the front surface of the green quantum package and the front surface of the second package, the processing method of the LED display module further comprising: packaging a display module containing the light-absorbing adhesive layer with a protective layer, a light transmittance of the protective layer being greater than or equal to 30%.

4. The processing method of the LED display module as claimed in claim 1, wherein before a step of placing the first LED chip on the first temporary substrate with the front surface of the first LED chip facing upward, and placing the second LED chip on the second temporary substrate with the front surface of second LED chip facing upward, the processing method of the LED display module further comprising: coating the first temporary substrate with a first release agent or a first release adhesive, and coating the second temporary substrate with a second release agent or a second release adhesive.

5. The processing method of the LED display module as claimed in claim 1, wherein
in a step of packaging the bottom and the side of the first LED chip with the first reflective adhesive, and packaging the bottom and the side of the second LED chip with the second reflective adhesive:
a thickness of the first reflective adhesive located outside the side of the first LED chip is greater than a first thickness, the first thickness being a sum of a thickness of an epitaxial layer of the first LED chip and a thickness of an electrode of the first LED chip,
a thickness of the second reflective adhesive located outside the side of the second LED chip is greater than a second thickness, the second thickness being a sum of a thickness of an epitaxial layer of the second LED chip and a thickness of an electrode of the second LED chip.

6. The processing method of the LED display module as claimed in claim 5, wherein
the thickness of the first reflective adhesive located outside the side of the first LED chip is smaller than a thickness of the first LED chip, the thickness of the first LED chip being equal to a sum of the thickness of a substrate of the first LED chip, the thickness of the epitaxial layer of the first LED chip and the thickness of the electrode of the first LED chip,
the thickness of the second reflective adhesive located outside the side of the second LED chip is smaller than a thickness of the second LED chip, the thickness of the second LED chip being equal to a sum of a thickness of the substrate of the second LED chip, the thickness of the epitaxial layer of the second LED chip and the thickness of the electrode of the second LED chip.

7. The processing method of the LED display module as claimed in claim 1, wherein
in a step of placing the first LED chip on the first temporary substrate with the front surface of the first LED chip facing upward, and placing the second LED chip on the second temporary substrate with the front surface of second LED chip facing upward, a plurality of first LED chips and a plurality of second LED chips are arranged at intervals,
wherein in a step of removing the first temporary substrate to obtain the first package containing the first LED chip, and removing the second temporary substrate to obtain the second package containing the second LED chip, after the first temporary substrate is removed, a plurality of first packages containing the first LED chip are obtained by performing cutting with one first LED chip as a unit, after the second temporary substrate is removed, a plurality of second packages containing the second LED chip are obtained by performing cutting with one second LED chip as a unit.

8. The processing method of the LED display module as claimed in claim 1, wherein in a step of removing the first temporary substrate to obtain the first package containing the first LED chip, and removing the second temporary substrate to obtain the second package containing the second LED chip, a ratio of a volume of the first package to a volume of the first LED chip ranges from 1.1 to 2, a ratio of a volume of the second package to a volume of the second LED chip ranges from 1.1 to 2.

9. The processing method of the LED display module as claimed in claim 1, wherein
the wavelength of the first LED chip ranges from 440 nm to 460 nm, the wavelength of the second LED chip ranges from 460 nm to 475 nm,
in a step of packaging the bottom and the side of the first LED chip with the first reflective adhesive, and packaging the bottom and the side of the second LED chip with the second reflective adhesive, a reflectivity of the first reflective adhesive is between 85% and 100%, a reflectivity of the second reflective adhesive is between 85% and 100%.

10. The processing method of the LED display module as claimed in claim 1, wherein in a step of packaging the front surface of the first LED chip with the first isolation layer, and packaging the front surface of the second LED chip with the second isolation layer, the first isolation layer comprises a first epoxy resin or a first silica gel, the second isolation layer comprises a second epoxy resin or a second silica gel.
